(19) United States
(12) Patent Application Publication
(10) Pub. No.: US 2026/0282683 A1
(43) Pub. Date: Sep. 17, 2026

(54) DISPLAY DEVICE AND ELECTRONIC DEVICE INCLUDING THE SAME

(71) Applicant: SAMSUNG DISPLAY CO., LTD., YONGIN-SI (KR)

(72) Inventors: Jun Ki JEONG, Yongin-si (KR); Hyun-Joon KIM, Yongin-si (KR)

(21) Appl. No.: 19/556,218

(22) Filed: Mar. 4, 2026

(30) Foreign Application Priority Data
Mar. 11, 2025 (KR) 10-2025-0031705

(51) Int. Cl. H10K 59/131; H10H 29/49

(52) U.S. Cl. CPC H10K 59/131; H10H 29/49

(57) ABSTRACT

A display device includes a display area. A display device includes a plurality of first power voltage lines each extending in a first direction in the display area and applying a first power voltage to pixels disposed in the display area. The display area includes a first area and a second area sequentially partitioned from each other in the first direction. The plurality of first power voltage lines includes a first-first power voltage line connected only to those pixels disposed in the display area that are disposed in the first area and a first-second power voltage line connected only to those pixels disposed in the display area that are disposed in the second area.

### CROSS-REFERENCE TO RELATED APPLICATIONS

This application claims priority under 35 U.S.C. §119 to Korean Patent Application No. 10-2025-0031705, filed on Mar. 11, 2025, in the Korean Intellectual Property Office, the disclosure of which is incorporated by reference herein in its entirety.

### TECHNICAL FIELD

The present disclosure relates to a display device, and an electronic device including the same.

### DISCUSSION OF THE RELATED ART

A light emitting display device that displays images by controlling the luminance of light emitting elements and a liquid crystal display device that displays images by controlling the transmittance of a liquid crystal layer are widely used as display devices. Unlike the liquid crystal display device, the light emitting display device might not require a separate light source such as a backlight, thereby reducing the thickness and weight of the display device. For example, the light emitting display device may exhibit high-quality characteristics such as low power consumption, high luminance, and response speed.

The display device may include a display area corresponding to a screen displaying images. A plurality of pixels may be disposed in the display area. The pixels may be implemented by light emitting diodes. The light emitting diode may include two electrodes and a light emitting layer disposed between the two electrodes. One of the two electrodes may be a pixel electrode individually provided for each pixel, and the other may be a common electrode commonly provided to a plurality of pixels.

Circuits and wirings for driving the pixel may be provided in the pixel. The pixel may be driven by applying various voltages to the circuits and wirings. However, in case that power voltage is non-uniformly applied to the circuits and wirings, the pixel may exhibit non-uniform brightness or color change in a periodic pattern.

### SUMMARY

Embodiments are intended to provide a display device with improved display quality by uniformly expressing colors of pixels.

Embodiments are intended to provide an electronic device with improved image quality.

In several embodiments of the present disclosure, a display device includes a display area. A display device includes a plurality of first power voltage lines each extending in a first direction in the display area and applying a first power voltage to pixels disposed in the display area. The display area includes a first area and a second area sequentially partitioned from each other in the first direction. The plurality of first power voltage lines includes a first-first power voltage line connected only to those pixels disposed in the display area that are disposed in the first area and a first-second power voltage line connected only to those pixels disposed in the display area that are disposed in the second area.

In various embodiments, the display device may include a first wiring disposed in the second area. The first wiring may be aligned with at least one of the plurality of first power voltage lines in the first direction. The first wiring may be spaced apart from each of the plurality of first power voltage lines. The pixels disposed in the second area that are not connected to the first-second power voltage line may be each connected to the first wiring.

In various embodiments, the display area may further include a third area and a fourth area sequentially partitioned from each other in the first direction. The plurality of first power voltage lines may further include a first-third power voltage line connected only to those pixels disposed in the display area that are disposed in the third area and a first-fourth power voltage line connected only to those pixels disposed in the display area that are disposed in the fourth area.

In various embodiments, the first area, the second area, the third area, and the fourth area may be sequentially disposed in the first direction.

In various embodiments, the display device may include a plurality of first wirings disposed in the second area, the third area, and the fourth area. Each of the plurality of first wirings may be aligned with one of the plurality of first power voltage lines in the first direction. Each of the plurality of first wirings may be spaced apart from each of the plurality of first power voltage lines. The plurality of first wirings may include a first-first wiring, a first-second wiring, and a first-third wiring. The pixels disposed in the second area, the pixels disposed in the third area, and the pixels disposed in the fourth area that are not connected to the first-first power voltage line may be each respectively connected to the first-first wiring. The pixels disposed in the third area and the pixels disposed in the fourth area that are not connected to the first-second power voltage line may be each respectively connected to the first-second wiring. The pixels disposed in the fourth area that are not connected to the first-third power voltage line may be each respectively connected to the first-third wiring.

In various embodiments, the display device may include a plurality of first power auxiliary lines each extending in a second direction and connecting the pixels disposed in the display area. The second direction may be perpendicular to the first direction. The plurality of first power auxiliary lines may include a first-first power auxiliary line connected to the pixels disposed in the first area and a first-second power auxiliary line connected to the pixels disposed in the second area.

In various embodiments, the display device may include a non-display area. The display device may include a first power voltage transmission line extending in a second direction in the non-display area. The second direction may be perpendicular to the first direction. Each of the plurality of first power voltage lines may be connected to the first power voltage transmission line in the non-display area.

In various embodiments, the display device may include a plurality of second power voltage lines each extending in the first direction in the display area and applying a second power voltage to the pixels disposed in the display area. The plurality of second power voltage lines may include a second-first power voltage line connected only to the pixels disposed in the first area and a second-second power voltage line connected only to the pixels disposed in the second area.

In various embodiments, the display device may include a plurality of first initialization voltage lines each extending in the first direction in the display area and applying a first initialization voltage to the pixels disposed in the display area. The plurality of first initialization voltage lines may include a first-first initialization voltage line connected only to the pixels disposed in the first area and a first-second initialization voltage line connected only to the pixels disposed in the second area.

In various embodiments, the first area may include a first-first area and a first-second area. The second area may include a second-first area and a second-second area.

In various embodiments, the first-first power voltage line may be connected only to those pixels disposed in the display area that are disposed in the first-first area and the first-second area. The first-second power voltage line may be connected only to those pixels disposed in the display area that are disposed in the second-first area and the second-second area.

In various embodiments, the first-first power voltage line may overlap with the first-second power voltage line and may be connected to the pixels disposed in the first area that are not connected to the first-second power voltage line.

In various embodiments, each of the pixels disposed in the display area may be driven in a plurality of cycles in one frame period.

In several embodiments of the present disclosure, a display device includes a display panel including a display area and a non-display area surrounding the display area. The display panel includes a plurality of first power voltage lines each extending in a first direction in the display panel and applying a first power voltage to pixels disposed in the display area. The display area includes a plurality of areas sequentially partitioned from each other in the first direction. Each of the pixels disposed in the display area is driven in a plurality of cycles in one frame period.

In various embodiments, a number of the plurality of areas may be equal to or greater than a number of the plurality of cycles.

In various embodiments, any one first power voltage line among the plurality of first power voltage lines may be connected only to those pixels disposed in the display area that are disposed in any one area among the plurality of areas. Adjacent first power voltage lines among the plurality of first power voltage lines may be connected only to those pixels disposed in the display area that are disposed in different areas.

In various embodiments, the display device may include a plurality of first wirings each extending in the first direction and a plurality of first power auxiliary lines each extending in a second direction perpendicular to the first direction. Each of the plurality of first wirings may be connected only to those pixels disposed in the display area that are not connected to any of the plurality of first power voltage lines.

In various embodiments, any one first power voltage line among the plurality of first power voltage lines may be connected only to those pixels disposed in the display area that are disposed in any one area among the plurality of areas. Each of the plurality of first power voltage lines connected to those pixels disposed in the display area that are disposed in different areas may be connected to those pixels disposed in the display area that are disposed on a same extension line in the first direction.

In various embodiments, the display device may include a flexible printed circuit film connected to the display panel, a driver integrated circuit chip disposed on the flexible printed circuit film, a printed circuit board connected to the flexible printed circuit film, and a power module disposed on the printed circuit board.

In several embodiments of the present disclosure, an electronic device includes a display device. The display device includes a display area and a plurality of first power voltage lines each extending in a first direction in the display area and applying a first power voltage to pixels disposed in the display area. The display area includes a first area and a second area sequentially partitioned from each other in the first direction. The plurality of first power voltage lines includes a first-first power voltage line connected only to those pixels disposed in the display area that are disposed in the first area and a first-second power voltage line connected only to those pixels disposed in the display area that are disposed in the second area.

### BRIEF DESCRIPTION OF THE DRAWINGS

The above and other features of the present disclosure will become apparent from the following description of the embodiments, taken in conjunction with the accompanying drawings, in which:

FIG. 1 is a schematic plan view of a display device, according to an embodiment of the present disclosure.

FIG. 2 is a cross-sectional view illustrating a portion of a display area included in the display device, according to an embodiment of the present disclosure.

FIG. 3 is an equivalent circuit diagram of a pixel included in a display device, according to an embodiment of the present disclosure.

FIG. 4 is a waveform diagram of signals applied to the pixel of FIG. 3, according to an embodiment of the present disclosure.

FIGS. 5, 6, 7, 8, 9, and 10 are schematic plan views of a display panel, according to an embodiment of the present disclosure.

FIG. 11 is a block diagram for explaining a signal processing process of electronic components included in an electronic device, according to an embodiment of the present disclosure.

FIG. 12 shows examples of electronic devices, according to several embodiments of the present disclosure.

### DETAILED DESCRIPTION

The present invention will now be described more fully hereinafter with reference to the accompanying drawings, in which several embodiments of the invention are shown. This invention may, however, be embodied in different forms and should not necessarily be construed as limited to the embodiments set forth herein. Rather, these embodiments are provided so that this disclosure will be thorough and complete, and will fully convey the scope of the invention to those skilled in the art.

In the present disclosure, same reference numerals are used for the same components in the drawings, and redundant descriptions of the same components might be omitted. To the extent that an element is not described in detail with respect to a figure, it may be understood that the element is at least similar to a corresponding element that has been described elsewhere within the present disclosure.

While each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like.

Throughout the specification, in several embodiments where a part such as a layer, film, region, plate, or the like is said to be "on" or "above" another part, this might include not only the case where it is "directly above" the other part, but also the case where there is another part in between. Conversely, in several embodiments where a part is said to be "directly above" another part, it might mean that there is no other part in between. Spatially relative terms are intended to include other directions in use, in operation, and/or in manufacturing, in addition to the direction depicted in the drawings. For example, in case that a device shown in the drawing is turned upside down, elements depicted as being positioned “under” other elements or features are positioned in a direction “on” the other elements or features. Therefore, in an embodiment, the term “under” may include both directions of “on” and “under”.

Throughout the specification, in several embodiments where a part is said to "include" a certain component, this means that it may further include other components rather than excluding other components unless specifically stated to the contrary.

Throughout the specification, "in plan view" means viewing the target part from above, and "a cross-sectional view" means viewing a cross-section of the target part cut vertically from the side.

Traditionally, a display may include a plurality of voltage lines, and the display may be driven by sending signals in multiple cycles. However, if a mesh including voltage lines is formed as a single structure, voltage drop between driving cycles may cause mura defect.

To resolve these challenges, a display panel and the mesh of voltage lines may be partitioned into a plurality of segments. By partitioning the mesh into more segments than the number of driving cycles, mura defect may be reduced or eliminated.

In several embodiments of the present disclosure, mesh voltage lines may be partitioned from each other. For example, mesh voltage lines may be divided into segments, and each segment may receive its own power and initialization voltage lines. Each segment of the mesh voltage lines may be non-overlapping and span over a different part of the display area. In several embodiments, each segment of the mesh voltage lines may include its own wirings and auxiliary lines. For example, even if a power voltage line is not connected all pixels in a segment, the power may be applied to all pixels in the segment through the wirings and auxiliary lines.

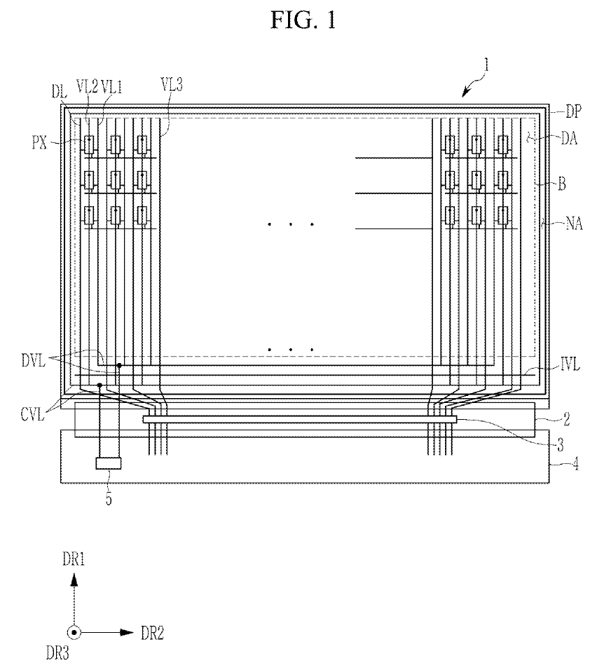

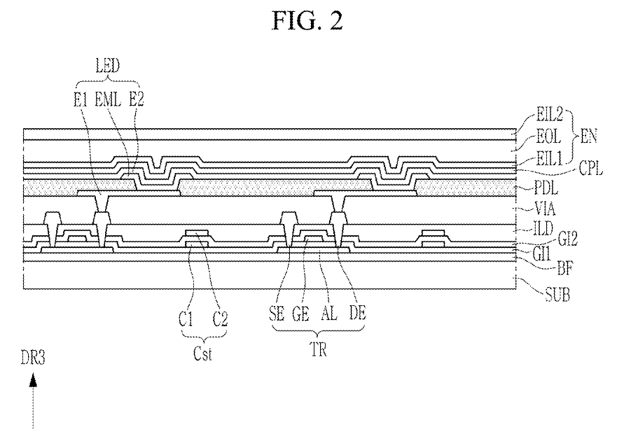

FIG. 1 is a schematic plan view of a display device according to an embodiment. FIG. 2 is a cross-section illustrating a portion of a display area of the display device according to an embodiment.

Referring to FIG. 1, the display device 1 may include a display panel DP, a flexible printed circuit film 2 connected to the display panel DP, a driver integrated circuit chip 3 disposed on the flexible printed circuit film 2, a printed circuit board 4 connected to the flexible printed circuit film 2, and a power module 5 disposed on the printed circuit board 4.

The display panel DP may include a display area DA corresponding to a screen displaying images, and a non-display area NA in which circuits and wirings for generating and transmitting various signals applied to the display area DA are disposed. The non-display area NA may be adjacent to the display area DA and may surround the display area DA. In FIG. 1, an inner area and an outer area of the boundary line B may be the display area DA and the non-display area NA, respectively.

The display area DA of the display panel DP may include pixels PX that may be disposed in a matrix. In addition, a data line DL transmitting a data voltage, a plurality of first power voltage lines VL1 transmitting a first power voltage, a plurality of second power voltage lines VL2 transmitting a second power voltage, and a plurality of first initialization voltage lines VL3 applying a first initialization voltage may be disposed in the display area DA. The plurality of first power voltage lines VL1, the plurality of second power voltage lines VL2, and the plurality of first initialization voltage lines VL3 may extend in a first direction DR1 in the display area DA. The first power voltage line VL1 may be a driving voltage line transmitting a driving voltage. The second power voltage line VL2 may be a common voltage line transmitting a common voltage. The first initialization voltage line VL3 may transmit a first initialization voltage. At least one of the first power voltage line VL1, the second power voltage line VL2, and the first initialization voltage line VL3 may be connected to an auxiliary voltage line extending in a second direction DR2 crossing the first direction DR1. In several embodiments, a second direction DR2 may be perpendicular to the first direction DR1. For example, the first power voltage line VL1 may extend in the second direction DR2 and be connected to a plurality of first power auxiliary lines connected to the pixels PX disposed in the display area DA. The second power voltage line VL2 may extend in the second direction DR2 and be connected to a plurality of second power auxiliary lines connected to the pixels PX disposed in the display area DA. The first initialization voltage line VL3 may extend in the second direction DR2 and be connected to a plurality of first initialization auxiliary lines connecting the pixels PX disposed in the display area DA.

The first power voltage line VL1, the second power voltage line VL2, and the first initialization voltage line VL3 may be respectively connected to lines transmitting the first power voltage, the second power voltage, and the first initialization voltage in the non-display area NA. In the non-display area NA of the display panel DP, a first power voltage transmission line DVL connected to the first power voltage line VL1, a second power voltage transmission line CVL connected to the second power voltage line VL2, a first initialization voltage transmission line IVL transmitting the first initialization voltage, and the like may be disposed. The first power voltage transmission line DVL, the second power voltage transmission line CVL, and the first initialization voltage transmission line IVL may each include portions extending in the first direction DR1.

In several embodiments, one end of the flexible printed circuit film 2 may be connected or bonded to the display panel DP, and the other end may be connected or bonded to the printed circuit board 4. A driver integrated circuit chip 3 including a data driver may be disposed on the flexible printed circuit film 2.

A power module 5 generating power voltages such as a first power voltage and a second power voltage may be disposed on the printed circuit board 4. The power module 5 may be provided in the form of an integrated circuit chip. In several embodiments, a signal controller controlling the data driver and the gate driver may be disposed on the printed circuit board 4.

Referring to FIG. 2, the display panel DP may include a substrate SUB, a transistor TR, a light emitting diode LED, and the like.

The substrate SUB may include a material having rigid characteristics such as glass or a material having flexible characteristics such as plastic. For example, the substrate SUB may be a glass substrate. In several embodiments, the substrate SUB may also include a polymer material such as polyimide.

A buffer layer BF may be disposed on the substrate SUB. The buffer layer BF may block impurities from the substrate SUB when the semiconductor layer AL is formed, and may planarize the surface of the substrate SUB to relieve stress of the semiconductor layer AL. The buffer layer BF may be an inorganic insulating layer that may include an inorganic insulating material, and may have a single-layer structure or a multi-layer structure.

A transistor TR may be disposed on the substrate SUB. For example, the transistor TR may be disposed on the buffer layer BF. A semiconductor layer AL of the transistor TR may be disposed on the buffer layer BF. The semiconductor layer AL may include a first region, a second region, and a channel region disposed between the first region and the second region. The semiconductor layer AL may include polycrystalline silicon or amorphous silicon, and may include, for example, low temperature polysilicon (LTPS). The semiconductor layer AL may include an oxide semiconductor. For example, the semiconductor layer AL may include an oxide semiconductor such as indium-gallium-zinc oxide (IGZO) including at least one of zinc (Zn), indium (In), gallium (Ga), tin (Sn), and mixtures thereof.

A first insulating layer GI1 may be disposed on the semiconductor layer AL. The first insulating layer GI1 may be referred to as a first gate insulating layer. The first insulating layer GI1 may include an inorganic insulating material. The first insulating layer GI1 may have a single-layer structure or a multi-layer structure.

A first gate conductive layer that may include a gate electrode GE of the transistor TR, a first electrode C1 of the storage capacitor Cst, and the like may be disposed on the first insulating layer GI1. The first gate conductive layer may include molybdenum (Mo), aluminum (Al), copper (Cu), titanium (Ti), and the like, and may have a single-layer structure or a multi-layer structure.

A second insulating layer GI2 may be disposed on the gate conductive layer. The second insulating layer GI2 may be referred to as a second gate insulating layer. The second insulating layer GI2 may include an inorganic insulating material. The second insulating layer GI2 may have a single-layer structure or a multi-layer structure.

A second gate conductive layer that may include a second electrode C2 of the storage capacitor Cst and the like may be disposed on the second insulating layer GI2. The second gate conductive layer may include molybdenum (Mo), aluminum (Al), copper (Cu), titanium (Ti), and the like, and may have a single-layer structure or a multi-layer structure. The first electrode C1 disposed on the first insulating layer GI1 and the second electrode C2 disposed on the second insulating layer GI2 may constitute the storage capacitor Cst.

An interlayer insulating layer ILD may be disposed on the second insulating layer GI2. The interlayer insulating layer ILD may include inorganic insulating materials such as silicon nitride, silicon oxide, and silicon oxynitride. The interlayer insulating layer ILD may have a single-layer structure or a multi-layer structure. An additional gate conductive layer may be disposed on the interlayer insulating layer ILD.

A data conductive layer that may include a first electrode SE and a second electrode DE of the transistor TR, or the like, may be disposed o5n the interlayer insulating layer ILD. The first electrode SE and the second electrode DE of the transistor TR may be respectively connected (for e.g., electrically) to the first semiconductor region and the second semiconductor region of the semiconductor layer AL through contact holes formed in the insulating layers GI1, GI2, and ILD. One of the first electrode SE and the second electrode DE may be a source electrode, and the other may be a drain electrode.

The data conductive layer may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), copper (Cu), and the like, and may have a single-layer structure or a multi-layer structure. For example, the data conductive layer may include a lower layer including a refractory metal, an intermediate layer including a low-resistivity metal, and an upper layer including a refractory metal. As used herein, the phrase “low-resistivity metal” may be understood to be not only one of the aforementioned metals but any other metal having an electrical resistivity that is equal to or lower than one of the aforementioned metals.

A planarization layer VIA may be disposed on the data conductive layer. For example, the planarization layer VIA may be disposed on the transistor TR. The planarization layer VIA may include organic insulating materials such as general-purpose polymers, polymer derivatives having phenolic groups, acrylic polymers, imide polymers, and siloxane polymers.

A light emitting diode LED, which is a light emitting element, may be disposed on the planarization layer VIA. The light emitting diode LED may include a pixel electrode E1, a light emitting layer EML, and a common electrode E2.

The pixel electrode E1 may be disposed on the planarization layer VIA. The pixel electrode E1 may be provided as an anode of the light emitting diode LED. The pixel electrode E1 may be electrically connected to the transistor TR. For example, the pixel electrode E1 may be connected to the second electrode DE of the transistor TR or a connection electrode connected to the second electrode DE through a contact hole formed in the planarization layer VIA.

The pixel electrode E1 may include a reflective conductive material or a semi-transmissive conductive material. In several embodiments, the pixel electrode E1 may also be formed of a transparent conductive material. The pixel electrode E1 may include a metal or a metal alloy. The pixel electrode E1 may have a single-layer structure or a multi-layer structure.

A pixel definition layer PDL having an opening overlapping with the pixel electrode E1 may be disposed on the planarization layer VIA. The opening may correspond to a light emitting area of the light emitting diode LED. The pixel definition layer PDL may include an organic insulating material.

A light emitting layer EML may be disposed on at least one of the pixel electrode E1 and the pixel definition layer PDL. In several embodiments, the light emitting layer EML may be a layer in which electro-optic conversion is performed through combination of electrons and holes, and may include at least one of organic and inorganic materials that emit light of a predetermined color. The light emitting layer EML may be disposed in the opening of the pixel definition layer PDL and may overlap with the pixel electrode E1. A portion of the light emitting layer EML may be disposed on the pixel definition layer PDL. The light emitting layer EML may include an organic light emitting diode or an inorganic light emitting diode.

A functional layer may be disposed below and/or above the light emitting layer EML. The functional layer may include at least one of a hole injection layer, a hole transport layer, an electron transport layer, and an electron injection layer. The functional layer may include a first functional layer disposed between the pixel electrode E1 and the light emitting layer EML, and a second functional layer disposed between the light emitting layer EML and the common electrode E2. The first functional layer may include at least one of a hole injection layer and a hole transport layer. The second functional layer may include at least one of an electron transport layer and an electron injection layer.

A common electrode E2 may be disposed on at least one of the light emitting layer EML and the functional layer. The common electrode E2 may be provided as a cathode of the light emitting diode LED. The common electrode E2 may be disposed throughout the display area DA described with reference to FIG. 1.

The common electrode E2 may include a metal or metal alloy having a low work function. For example, light transmittance may be achieved by forming a thin layer of a metal or metal alloy with a low work function. The common electrode E2 may also include a transparent conductive oxide.

The common electrode E2 may constitute the light emitting diode LED together with the pixel electrode E1 and the light emitting layer EML.

A capping layer CPL may be disposed on the common electrode E2. The capping layer CPL may improve light efficiency through refractive index adjustment.

An encapsulation layer EN may be disposed on the capping layer CPL. The encapsulation layer EN may encapsulate the light emitting diode LED including the light emitting layer EML to prevent moisture or oxygen from penetrating from the outside. The encapsulation layer EN may be a thin film encapsulation layer including one or more inorganic layers EIL1 and EIL2 and one or more organic layers EOL.

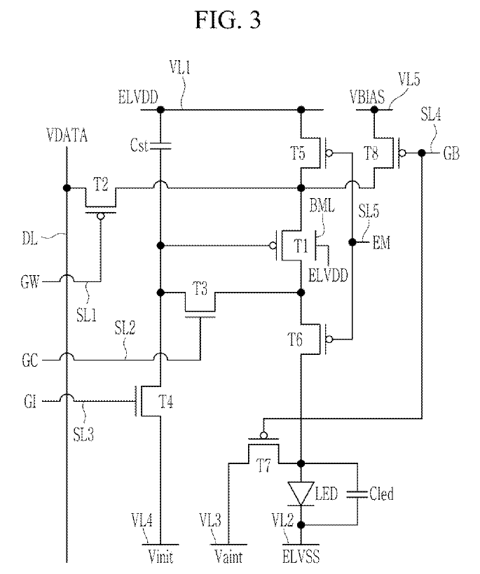

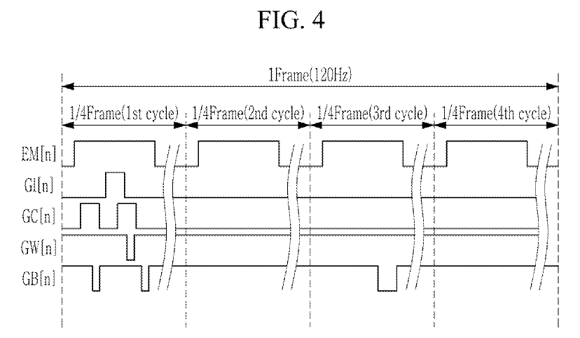

FIG. 3 is an equivalent circuit diagram of a pixel included in a display device according to an embodiment. FIG. 4 is a waveform diagram of signals applied to the pixel of FIG. 3.

Referring to FIGS. 3 and 4, a pixel may include a plurality of transistors T1, T2, T3, T4, T5, T6, T7, T8, a storage capacitor Cst, and a light emitting diode LED. The transistors and capacitors except for the light emitting diode LED may constitute a pixel circuit unit. The pixel may also include a diode capacitor Cled having the anode and cathode of the light emitting diode LED as two electrodes. The diode capacitor Cled is a capacitor configured by overlapping two electrodes of the light emitting diode LED and is a capacitor attached to the light emitting diode LED. In several embodiments, the diode capacitor Cled may be omitted.

A plurality of wirings VL1, VL2, VL3, VL4, VL5, SL1, SL2, SL3, SL4, SL5, DL may be connected to the pixel PX. The plurality of wirings may include a first power voltage line VL1, a second power voltage line VL2, a first initialization voltage line VL3, a second initialization voltage line VL4, a bias voltage line VL5, a first scan line SL1, a second scan line SL2, a third scan line SL3, a fourth scan line SL4, a light emission control line SL5, and a data line DL. The first scan line SL1 may be connected to a scan driver to transmit a first scan signal GW to the second transistor T2. A voltage having an opposite polarity to the voltage applied to the first scan line SL1 may be applied to the second scan line SL2. For example, in several embodiments where a negative voltage is applied to the first scan line SL1, a positive voltage may be applied to the second scan line SL2. The second scan line SL2 may transmit a second scan signal GC to the third transistor T3. The third scan line SL3 may transmit a third scan signal GI to the fourth transistor T4. The fourth scan line SL4 may transmit a fourth scan signal GB to the seventh transistor T7 and the eighth transistor T8. The light emission control line SL5 may transmit a light emission control signal EM to the fifth transistor T5 and the sixth transistor T6.

The data line DL is a wiring that transmits a data voltage VDATA generated by a data driver, and accordingly, the magnitude of the light emission current transmitted to the light emitting diode LED may change, so that the luminance emitted by the light emitting diode LED may also change. The first power voltage line VL1 may apply a driving voltage ELVDD, and the second power voltage line VL2 may apply a common voltage ELVSS to the cathode of the light emitting diode LED. The first initialization voltage line VL3 may transmit a first initialization voltage Vaint, and the second initialization voltage line VL4 may transmit a second initialization voltage Vinit. The bias voltage line VL5 may apply a bias voltage VBIAS. The voltages applied to the first power voltage line VL1, the second power voltage line VL2, the first initialization voltage line VL3, the second initialization voltage line VL4, and the bias voltage line VL5 may each be constant voltages.

The first transistor T1 may be a p-type transistor and may have a silicon semiconductor as the semiconductor layer. The first transistor T1 may be referred to as a driving transistor. The first transistor T1 may be a transistor that controls the magnitude of light emission current output to the anode of the light emitting diode LED according to the magnitude of the voltage of the gate electrode of the first transistor T1 (for example, the voltage stored in the storage capacitor Cst). Because the brightness of the light emitting diode LED is controlled according to the magnitude of the light emission current output to the anode electrode of the light emitting diode LED, the light emission luminance of the light emitting diode LED may be controlled according to the data voltage VDATA applied to the pixel. For this purpose, the first electrode of the first transistor T1 may be arranged to receive the driving voltage ELVDD and may be connected (for e.g., electrically) to the first power voltage line VL1 via the fifth transistor T5. In several embodiments, the first electrode of the first transistor T1 may also be connected to the second electrode of the second transistor T2 to receive the data voltage VDATA, and may also be connected to the second electrode of the eighth transistor T8 to receive the bias voltage VBIAS. The second electrode of the first transistor T1 outputs light emission current to the light emitting diode LED and may be connected to the anode of the light emitting diode LED via the sixth transistor T6. In addition, the second electrode of the first transistor T1 may also be connected to the third transistor T3 to transmit the data voltage VDATA applied to the first electrode to the third transistor T3. The gate electrode of the first transistor T1 may be connected to the first electrode of the storage capacitor Cst. For example, the voltage of the gate electrode of the first transistor T1 may change according to the voltage stored in the storage capacitor Cst, and accordingly, the light emission current output by the first transistor T1 may be changed. The storage capacitor Cst may maintain the voltage of the gate electrode of the first transistor T1 constant during one cycle of one frame. The gate electrode of the first transistor T1 may also be connected to the third transistor T3 so that the data voltage VDATA applied to the first electrode of the first transistor T1 may pass through the third transistor T3 and be transmitted to the gate electrode of the first transistor T1. The gate electrode of the first transistor T1 may also be connected to the fourth transistor T4 to receive the second initialization voltage Vinit and be initialized. In several embodiments, the first transistor T1 may further include a metal layer BML overlapping with the channel, and the metal layer BML may protect the semiconductor layer of the first transistor T1 during the crystallization process of the semiconductor layer.

The second transistor T2 may be a p-type transistor and may have a silicon semiconductor as the semiconductor layer. The second transistor T2 may be a transistor that receives the data voltage VDATA into the pixel. The gate electrode of the second transistor T2 may be connected (for e.g., electrically) to the first scan line SL1. The first electrode of the second transistor T2 may be connected to the data line DL. The second electrode of the second transistor T2 may be connected to the first electrode of the first transistor T1. In several embodiments where the second transistor T2 is turned on by a negative voltage among the first scan signal GW transmitted through the first scan line SL1, the data voltage VDATA transmitted through the data line DL may be transmitted to the first electrode of the first transistor T1, and consequently, the data voltage VDATA may be transmitted to the gate electrode of the first transistor T1 and stored in the storage capacitor Cst.

The third transistor T3 may be an n-type transistor and may have an oxide semiconductor as the semiconductor layer. The third transistor T3 may electrically connect the second electrode of the first transistor T1 and the gate electrode of the first transistor T1. The third transistor T3 may be a transistor that allows the data voltage VDATA to be stored in the first electrode of the storage capacitor Cst after being compensated by the threshold voltage of the first transistor T1. The gate electrode of the third transistor T3 may be connected to the second scan line SL2, and the first electrode of the third transistor T3 may be connected to the second electrode of the first transistor T1. The second electrode of the third transistor T3 may be connected to the first electrode of the storage capacitor Cst and the gate electrode of the first transistor T1. The third transistor T3 may be turned on by a positive voltage of the second scan signal GC transmitted through the second scan line SL2, and may connect the gate electrode of the first transistor T1 and the second electrode of the first transistor T1, and may transmit the voltage applied to the gate electrode of the first transistor T1 to the first electrode of the storage capacitor Cst to store it in the storage capacitor Cst. For example, the voltage stored in the storage capacitor Cst is the voltage of the gate electrode of the first transistor T1 in case that the first transistor T1 is turned off, and may be stored in a state where the threshold voltage value of the first transistor T1 is compensated.

The fourth transistor T4 may be an n-type transistor and may have an oxide semiconductor as the semiconductor layer. The fourth transistor T4 may initialize the gate electrode of the first transistor T1 and the first electrode of the storage capacitor Cst. The gate electrode of the fourth transistor T4 may be connected to the third scan line SL3, and the first electrode of the fourth transistor T4 may be connected to the second initialization voltage line VL4. The second electrode of the fourth transistor T4 may be connected to the second electrode of the third transistor T3, the first electrode of the storage capacitor Cst, and the gate electrode of the first transistor T1. The fourth transistor T4 may be turned on by a positive voltage among the third scan signal GI transmitted through the third scan line SL3, and may transmit the second initialization voltage Vinit to the gate electrode of the first transistor T1 and the first electrode of the storage capacitor Cst to initialize them.

The fifth transistor T5 and the sixth transistor T6 may be p-type transistors and may have silicon semiconductors as the semiconductor layer.

The driving voltage ELVDD may be transmitted to the first transistor T1 through the fifth transistor T5. The gate electrode of the fifth transistor T5 may be connected to the light emission control line SL5, the first electrode of the fifth transistor T5 may be connected to the first power voltage line VL1, and the second electrode of the fifth transistor T5 may be connected to the first electrode of the first transistor T1.

The sixth transistor T6 may transmit the light emission current output from the first transistor T1 to the light emitting diode LED. The gate electrode of the sixth transistor T6 may be connected to the light emission control line SL5, the first electrode of the sixth transistor T6 may be connected to the second electrode of the first transistor T1, and the second electrode of the sixth transistor T6 may be connected to the anode of the light emitting diode LED.

The seventh transistor T7 may be a p-type transistor and may have a silicon semiconductor as the semiconductor layer. The seventh transistor T7 may initialize the anode of the light emitting diode LED. The gate electrode of the seventh transistor T7 may be connected to the fourth scan line SL4, the first electrode of the seventh transistor T7 may be connected to the anode of the light emitting diode LED, and the second electrode of the seventh transistor T7 may be connected to the first initialization voltage line VL3. In several embodiments where the seventh transistor T7 is turned on by a negative voltage of the fourth scan line SL4, the first initialization voltage Vaint may be applied to the anode of the light emitting diode LED to initialize it.

The eighth transistor T8 may be a p-type transistor and may include a silicon semiconductor. The eighth transistor T8 may transmit a bias voltage VBIAS to the first electrode of the first transistor T1. The gate electrode of the eighth transistor T8 may be connected to the fourth scan line SL4, the first electrode of the eighth transistor T8 may be connected to the bias voltage line VL5, and the second electrode of the eighth transistor T8 may be connected to the first electrode of the first transistor T1. In case that the eighth transistor T8 is turned on by a negative voltage of the fourth scan line SL4, the bias voltage VBIAS may be applied to the first electrode of the first transistor T1 so that the characteristics of the first transistor T1 may be maintained constant.

Although a pixel PX has been described as including eight transistors T1, T2, T3, T4, T5, T6, T7, T8 and two capacitors Cst, Cled, the present disclosure is not necessarily limited thereto, and the number and connection of the transistors and capacitors may be variously changed. In several embodiments, the type of each transistor T1, T2, T3, T4, T5, T6, T7 and the material of the semiconductor layer may be variously changed.

Referring to FIGS. 3 and 4, a pixel may be driven in a plurality of cycles in one frame period. The pixel may be driven in 4 cycles in one frame period. For example, the pixel may be driven in a first cycle, a second cycle, a third cycle, and a fourth cycle in one frame period. The light emitting diode LED may emit light while a low level light emission control signal EM is applied in each cycle.

In the first cycle, in several embodiments where a high level light emission control signal EM is supplied, the fifth transistor T5 and the sixth transistor T6 may be turned off. In several embodiments where the fifth transistor T5 is turned off, the electrical connection between the first power voltage line VL1 and the first transistor T1 may be blocked. In several embodiments where the sixth transistor T6 is turned off, the electrical connection between the first transistor T1 and the light emitting diode LED may be blocked. For example, the light emitting diode LED may be set to a non-light-emitting state during a period in which the high level light emission control signal EM is supplied.

A high level second scan signal GC may be supplied from the second scan line SL2 in a section where the high level light emission control signal EM is supplied. In several embodiments where the high level second scan signal GC is supplied, the third transistor T3 may be turned on, and the first transistor T1 may be connected in a diode form.

A low level fourth scan signal GB may be supplied to the fourth scan line SL4 to overlap with the high level second scan signal GC for a partial period, by which the seventh transistor T7 and the eighth transistor T8 may be turned on.

In several embodiments where the seventh transistor T7 is turned on, the first initialization voltage Vaint may be supplied, and the light emitting diode LED may be initialized by the first initialization voltage Vaint.

In several embodiments where the eighth transistor T8 is turned on, the bias voltage VBIAS may be supplied. The bias voltage VBIAS may pass through the first transistor T1 connected in a diode form. For example, the voltage difference between nodes connected to the first transistor T1 may be reduced to the threshold voltage level of the first transistor T1. Therefore, the magnitude of the gate-source voltage VGS of the first transistor T1 may be reduced, and the first transistor T1 may be set to an off bias state.

After the high level second scan signal GC is supplied, a high level third scan signal GI may be supplied to the third scan line SL3, by which the fourth transistor T4 may be turned on. In several embodiments where the fourth transistor T4 is turned on, the gate electrode of the first transistor T1 may be initialized by the second initialization voltage Vinit. For example, the bias voltage VBIAS may be applied to the first transistor T1 to cause a body effect, and accordingly, the threshold voltage may be shifted.

A high level second scan signal GC may be supplied to the second scan line SL2 to overlap with the high level third scan signal GI for a partial period. After the high level second scan signal GC is supplied, a low level first scan signal GW may be supplied to the first scan line SL1. In several embodiments where the high level second scan signal GC is supplied to the second scan line SL2, the third transistor T3 may be turned on so that the first transistor T1 may be connected in a diode form.

In several embodiments where the low level first scan signal GW is supplied, the second transistor T2 may be turned on so that the data voltage VDATA may be supplied from the data line DL. The supplied data voltage may pass through the first transistor T1 connected in a diode form. For example, the voltage passing through the first transistor T1 may be stored in the storage capacitor Cst.

Thereafter, a low level fourth scan signal GB may be supplied to the fourth scan line SL4, and the seventh transistor T7 and the eighth transistor T8 may be turned on. In several embodiments where the seventh transistor T7 is turned on, the light emitting diode LED may be initialized by the first initialization voltage Vaint.

In several embodiments where the eighth transistor T8 is turned on, the bias voltage VBIAS may be supplied, and the first transistor T1 may be set to an on bias state. A period during which scan signals are not supplied may be maintained for the first transistor T1 to be set to a stable on bias state.

Thereafter, in several embodiments where a low level light emission control signal EM is applied to the light emission control line SL5, the fifth transistor T5 and the sixth transistor T6 may be turned on. In several embodiments where the fifth transistor T5 is turned on, the first power voltage line VL1 and the first transistor T1 may be electrically connected, and in several embodiments where the sixth transistor T6 is turned on, the first transistor T1 and the light emitting diode LED may be electrically connected. In the first cycle, the driving voltage ELVDD may be supplied from the first power voltage line VL1 to the second power voltage line VL2 via the light emitting diode LED, and the light emitting diode LED may emit light with luminance corresponding to the driving current.

In the second cycle, the third cycle, and the fourth cycle, the light emission control signal EM may be alternately applied at high level and low level, and the first scan signal GW, the second scan signal GC, and the third scan signal GI may be maintained at high level or low level. The fourth scan signal GB may be applied at low level in the third cycle. For example, non-light-emitting periods may be periodically repeated in one frame period, reducing luminance differences between frames and reducing power consumption. In several embodiments, the first transistor T1 may be periodically set to an on bias state by the low level fourth scan signal GB, and accordingly, the characteristics of the first transistor T1 may be maintained constant to minimize luminance changes.

In several embodiments, the pixel may be driven in 4 cycles during one frame, improving display quality and reducing power consumption. However, as the light emission control signal EM changes from a high level to a low level in a 4-cycle period is applied, voltage fluctuation of the driving voltage ELVDD may occur at the beginning and middle of one cycle. The common voltage ELVSS may fluctuate in response to the voltage fluctuation of the driving voltage ELVDD. For example, in several embodiments where the driving voltage ELVDD rises, the common voltage ELVSS may fall, and in case that the driving voltage ELVDD falls, the common voltage ELVSS may rise. In several embodiments where the driving voltage ELVDD falls and the common voltage ELVSS rises, the gate-source voltage VGS of the first transistor T1 may fall and be displayed as a dark portion. In several embodiments where the driving voltage ELVDD rises and the common voltage ELVSS falls, the gate-source voltage VGS of the first transistor T1 may rise and be displayed as a bright portion. As the dark portion and bright portion are repeated, mura (defect) according to cycles may occur.

As shown in FIG. 1, because the first power voltage line VL1 and the second power voltage line VL2 are connected to the entire display area DA in the first direction DR1, in case that mura occurs, mura may be manifested in the entire display area DA. To avoid or reduce mura in the entire display area DA, the display area may be partitioned into a plurality of areas, and the first power voltage line VL1, the second power voltage line VL2, and the first initialization voltage line VL3 may be independently connected to the partitioned areas, for example, the driving voltage ELVDD, the common voltage ELVSS, and the first initialization voltage Vaint may be independently applied to each area. Therefore, the continuous occurrence of mura in the entire display area may be suppressed.

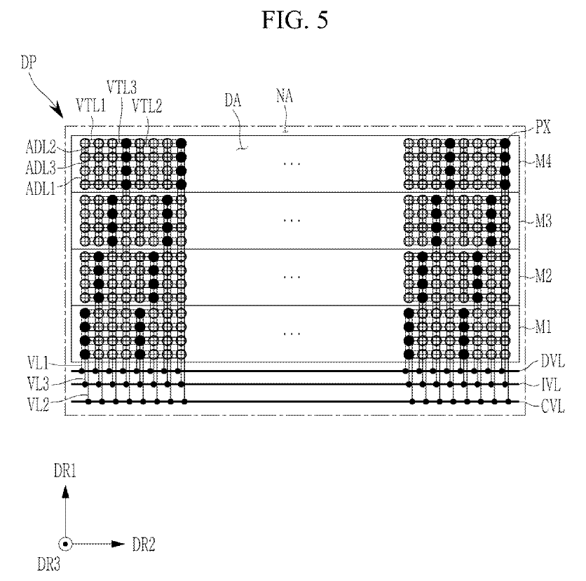

Hereinafter, with reference to FIGS. 5-10, partitioning of the display area to suppress mura occurring in the entire display area, and connections of the first power voltage line VL1, the second power voltage line VL2, and the first initialization voltage line VL3 to the partitioned display area(s) will be described.

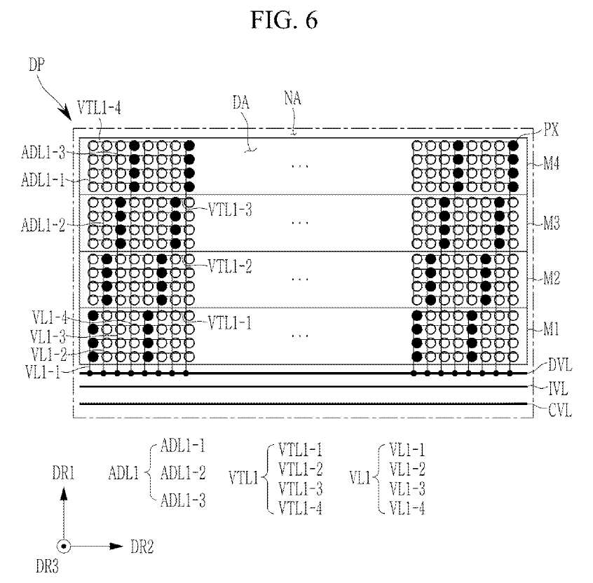

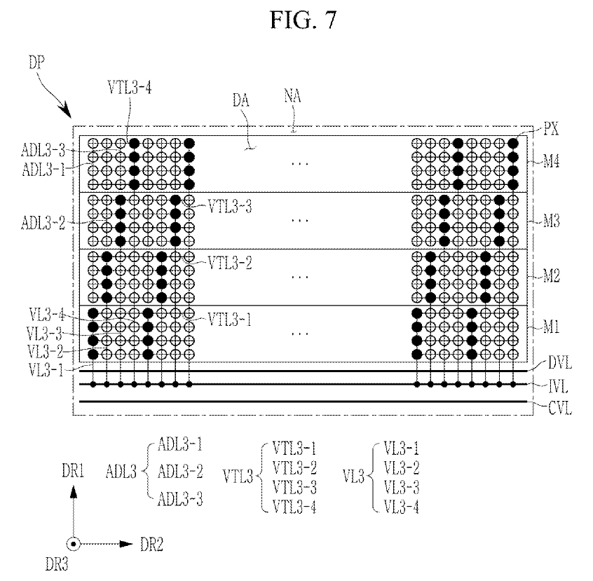

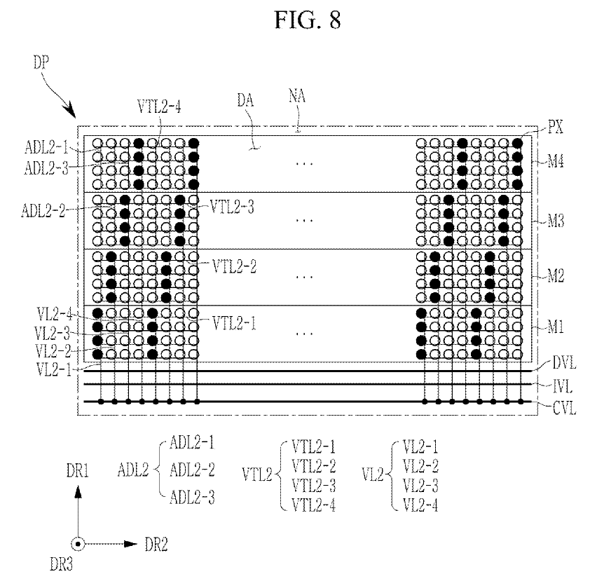

FIGS. 5-8 are schematic plan views of a display panel according to an embodiment. In FIGS. 5-8, each circle may represent one pixel PX. A filled circle represents a pixel PX among the pixels PX to which the first power voltage line VL1, the second power voltage line VL2, and the first initialization voltage line VL3 are directly connected (for e.g., electrically). An empty circle represents a pixel PX among the pixels PX to which the first power voltage line VL1, the second power voltage line VL2, and the first initialization voltage line VL3 are not directly connected. FIG. 5 shows connections between the pixels PX and the first power voltage line VL1, the second power voltage line VL2, and the first initialization voltage line VL3. To clearly show the connections between the pixels PX and the wirings, FIG. 6 shows connections between the pixels PX and the first power voltage line VL1, FIG. 7 shows connections between the pixels PX and the first initialization voltage line VL3, and FIG. 8 shows connections between the pixels PX and the second power voltage line VL2.

Referring to FIG. 5, the display panel DP may include a display area DA and a non-display area NA, and the display area DA may include a plurality of areas partitioned from each other. In several embodiments where the light emitting elements are driven in a plurality of cycles in one frame period, the plurality of areas may be equal to or greater than the number of the plurality of cycles. The display area DA may include a first area M1, a second area M2, a third area M3, and a fourth area M4. The first area M1, the second area M2, the third area M3, and the fourth area M4 may be sequentially disposed in the first direction DR1. A plurality of pixels PX may be disposed in the display area DA.

The first power voltage line VL1, the second power voltage line VL2, and the first initialization voltage line VL3 may be disposed in the display panel DP. The plurality of first power voltage lines VL1, the plurality of second power voltage lines VL2, and the plurality of first initialization voltage lines VL3 may extend in the first direction DR1 in the display area DA and may be connected to the pixels PX in the display area DA. The plurality of first power voltage lines VL1, the plurality of second power voltage lines VL2, and the plurality of first initialization voltage lines VL3 disposed in the display area DA may be respectively connected to the first power voltage transmission line DVL, the second power voltage transmission line CVL, and the first initialization voltage transmission line IVL extending in the second direction DR2 in the non-display area NA.

The first wiring ADL1, the second wiring ADL2, and the third wiring ADL3 may be disposed in the display area DA. The first wiring ADL1 may be disposed at a position where the first power voltage line VL1 extends and may be separated from the first power voltage line VL1. For example, the first wiring ADL1 may be disposed to be aligned with the first power voltage line VL1, and the first wiring ADL1 may be spaced apart from the first power voltage line VL1. The first wiring ADL1 may be connected to pixels PX not connected to the first power voltage line VL1 among the pixels PX arranged in the first direction DR1. The second wiring ADL2 may be disposed at a position where the second power voltage line VL2 extends and may be separated from the second power voltage line VL2. For example, the second wiring ADL2 may be disposed to be aligned with the second power voltage line VL2. The third wiring ADL3 may be disposed at a position where the first initialization voltage line VL3 extends and may be separated from the first initialization voltage line VL3. For example, the third wiring ADL3 may be disposed to be aligned with the first power voltage line VL3. The second wiring ADL2 may be connected to pixels PX not connected to the second power voltage line VL2 among the pixels PX arranged in the first direction DR1. The third wiring ADL3 may be connected to pixels PX not connected to the first initialization voltage line VL3 among the pixels PX arranged in the first direction DR1.

The first power auxiliary line VTL1, the second power auxiliary line VTL2, and the first voltage auxiliary line VTL3 may be disposed in the display area DA. The first power auxiliary line VTL1, the second power auxiliary line VTL2, and the first voltage auxiliary line VTL3 may extend in the second direction DR2. The first power auxiliary line VTL1 may connect pixels PX arranged in the second direction DR2 to transmit a first power voltage (for example, a driving voltage ELVDD). The second power auxiliary line VTL2 may connect pixels PX arranged in the second direction DR2 to transmit a second power voltage (for example, a common voltage ELVSS). The first voltage auxiliary line VTL3 may connect pixels PX arranged in the second direction DR2 to transmit the first initialization voltage Vaint.

The first wiring ADL1 and the first power auxiliary line VTL1 may be disposed in the display area DA, so that even if the first power voltage line VL1 is not connected to all pixels PX, the first power voltage may be applied to all pixels PX. The second wiring ADL2 and the second power auxiliary line VTL2 may be disposed in the display area DA, so that even if the second power voltage line VL2 is not connected to all pixels PX, the second power voltage may be applied to all pixels PX. The third wiring ADL3 and the first voltage auxiliary line VTL3 may be disposed in the display area DA, so that even if the first initialization voltage line VL3 is not connected to all pixels PX, the first initialization voltage may be applied to all pixels PX.

Referring to FIGS. 5 and 6, the first power voltage line VL1 may include a first-first power voltage line VL1-1, a first-second power voltage line VL1-2, a first-third power voltage line VL1-3, and a first-fourth power voltage line VL1-4. The first-first power voltage line VL1-1 may extend in the first direction DR1 in the first area M1. The first-second power voltage line VL1-2 may extend in the first direction DR1 across the first area M1 and the second area M2. The first-third power voltage line VL1-3 may extend in the first direction DR1 across the first area M1, the second area M2, and the third area M3. The first-fourth power voltage line VL1-4 may extend in the first direction DR1 across the first area M1, the second area M2, the third area M3, and the fourth area M4. The first-first power voltage line VL1-1 may be connected only to pixels disposed in the first area M1. The first-second power voltage line VL1-2 may be connected only to pixels disposed in the second area M2. The first-third power voltage line VL1-3 may be connected only to pixels disposed in the third area M3. The first-fourth power voltage line VL1-4 may be connected only to pixels disposed in the fourth area M4. For example, the first power voltage may be independently applied to the four areas M1, M2, M3, M4 partitioned from each other in the display area DA. Therefore, in several embodiments where one frame is driven in four cycles and mura phenomenon occurs between cycles, even if mura phenomenon occurs in any one area, mura phenomenon may not be transmitted to other areas.

The first wiring ADL1 may include a first-first wiring ADL1-1, a first-second wiring ADL1-2, and a first-third wiring ADL1-3. The first-first wiring ADL1-1 is disposed at a position where the first-first power voltage line VL1-1 extends, and may be separated from the first-first power voltage line VL1-1. For example, the first-first wiring ADL1-1 may be disposed to be aligned with the first-first power voltage line VL1-1. The first-second wiring ADL1-2 is disposed at a position where the first-second power voltage line VL1-2 extends, and may be separated from the first-second power voltage line VL1-2. For example, the first-second wiring ADL1-2 may be disposed to be aligned with the first- second power voltage line VL1-2. The first-third wiring ADL1-3 is disposed at a position where the first-third power voltage line VL1-3 extends, and may be separated from the first-third power voltage line VL1-3. For example, the first-third wiring ADL1-3 may be disposed to be aligned with the first- third power voltage line VL1-3. The first-first wiring ADL1-1 disposed in the second area M2 may be separated from the first-first wiring ADL1-1 disposed in the third area M3, and the first-first wiring ADL1-1 disposed in the third area M3 may be separated from the first-first wiring ADL1-1 disposed in the fourth area M4. The first-second wiring ADL1-2 disposed in the third area M3 may be separated from the first-second wiring ADL1-2 disposed in the fourth area M4.

Pixels PX not connected to the first-first power voltage line VL1-1 in the first area M1 may be connected by a first-first power auxiliary line VTL1-1 extending in the second direction DR2 to apply the first power voltage. Pixels PX not connected to the first-second power voltage line VL1-2 in the second area M2 may be connected by a first-first wiring ADL1-1 extending in the first direction DR1 and a first-second power auxiliary line VTL1-2 extending in the second direction DR2 to apply the first power voltage. Pixels PX not connected to the first-third power voltage line VL1-3 in the third area M3 may be connected by a first-first wiring ADL1-1 and a first-second wiring ADL1-2 extending in the first direction DR1, and a first-third power auxiliary line VTL1-3 extending in the second direction DR2 to apply the first power voltage. Pixels PX not connected to the first-fourth power voltage line VL1-4 in the fourth area M4 may be connected by a first-first wiring ADL1-1, a first-second wiring ADL1-2, and a first-third wiring ADL1-3 extending in the first direction DR1, and a first-fourth power auxiliary line VTL1-4 extending in the second direction DR2 to apply the first power voltage. In several embodiments, even though the first power voltage line VL1 is not independently connected to each of the pixels PX in the areas M1, M2, M3, M4 partitioned in the display area DA, the first power voltage may be applied to all pixels PX.

Referring to FIGS. 5 and 7, the first initialization voltage line VL3 may include a first-first initialization voltage line VL3-1, a first-second initialization voltage line VL3-2, a first-third initialization voltage line VL3-3, and a first-fourth initialization voltage line VL3-4. The first-first initialization voltage line VL3-1 may extend in the first direction DR1 in the first area M1. The first-second initialization voltage line VL3-2 may extend in the first direction DR1 across the first area M1 and the second area M2. The first-third initialization voltage line VL3-3 may extend in the first direction DR1 across the first area M1, the second area M2, and the third area M3. The first-fourth initialization voltage line VL3-4 may extend in the first direction DR1 across the first area M1, the second area M2, the third area M3, and the fourth area M4. The first-first initialization voltage line VL3-1 may be connected only to pixels disposed in the first area M1. The first-second initialization voltage line VL3-2 may be connected only to pixels disposed in the second area M2. The first-third initialization voltage line VL3-3 may be connected only to pixels disposed in the third area M3. The first-fourth initialization voltage line VL3-4 may be connected only to pixels disposed in the fourth area M4. For example, the first initialization voltage may be independently applied to the four areas M1, M2, M3, M4 partitioned from each other in the display area DA. Therefore, in several embodiments where one frame is driven in four cycles and mura phenomenon occurs between cycles, even if mura phenomenon occurs in any one area, mura phenomenon may not be transmitted to other areas.

The third wiring ADL3 may include a third-first wiring ADL3-1, a third-second wiring ADL3-2, and a third-third wiring ADL3-3. The third-first wiring ADL3-1 may be disposed at a position where the first-first initialization voltage line VL3-1 extends and may be separated from the first-first initialization voltage line VL3-1. The third-second wiring ADL3-2 may be disposed at a position where the first-second initialization voltage line VL3-2 extends and may be separated from the first-second initialization voltage line VL3-2. The third-third wiring ADL3-3 may be disposed at a position where the first-third initialization voltage line VL3-3 extends and may be separated from the first-third initialization voltage line VL3-3. The third-first wiring ADL3-1 disposed in the second area M2 may be separated from the third-first wiring ADL3-1 disposed in the third area M3, and the third-first wiring ADL3-1 disposed in the third area M3 may be separated from the third-first wiring ADL3-1 disposed in the fourth area M4. The third-second wiring ADL3-2 disposed in the third area M3 may be separated from the third-second wiring ADL3-2 disposed in the fourth area M4.

Pixels PX not connected to the first-first initialization voltage line VL3-1 in the first area M1 may be connected by a first-first voltage auxiliary line VTL3-1 extending in the second direction DR2 to apply the first initialization voltage. Pixels PX not connected to the first-second initialization voltage line VL3-2 in the second area M2 may be connected by a third-first wiring ADL3-1 extending in the first direction DR1 and a first-second voltage auxiliary line VTL3-2 extending in the second direction DR2 to apply the first initialization voltage. Pixels PX not connected to the first-third initialization voltage line VL3-3 in the third area M3 may be connected by a third-first wiring ADL3-1 and a third-second wiring ADL3-2 extending in the first direction DR1, and a first-third voltage auxiliary line VTL3-3 extending in the second direction DR2 to apply the first initialization voltage. Pixels PX not connected to the first-fourth initialization voltage line VL3-4 in the fourth area M4 may be connected by a third-first wiring ADL3-1, a third-second wiring ADL3-2, and a third-third wiring ADL3-3 extending in the first direction DR1, and a first-fourth voltage auxiliary line VTL3-4 extending in the second direction DR2 to apply the first initialization voltage. Accordingly, even though the first initialization voltage line VL3 is not independently connected to each of the pixels PX in the areas M1, M2, M3, M4 partitioned in the display area DA, the first initialization voltage may be applied to all pixels PX.

Referring to FIGS. 5 and 8, the second power voltage line VL2 may include a second-first power voltage line VL2-1, a second-second power voltage line VL2-2, a second-third power voltage line VL2-3, and a second-fourth power voltage line VL2-4. The second-first power voltage line VL2-1 may extend in the first direction DR1 in the first area M1. The second-second power voltage line VL2-2 may extend in the first direction DR1 across the first area M1 and the second area M2. The second-third power voltage line VL2-3 may extend in the first direction DR1 across the first area M1, the second area M2, and the third area M3. The second-fourth power voltage line VL2-4 may extend in the first direction DR1 across the first area M1, the second area M2, the third area M3, and the fourth area M4. The second-first power voltage line VL2-1 may be connected only to pixels disposed in the first area M1. The second-second power voltage line VL2-2 may be connected only to pixels disposed in the second area M2. The second-third power voltage line VL2-3 may be connected only to pixels disposed in the third area M3. The second-fourth power voltage line VL2-4 may be connected only to pixels disposed in the fourth area M4. Accordingly, the second power voltage (for example, common voltage) may be independently applied to the four areas M1, M2, M3, M4 partitioned from each other in the display area DA. Therefore, in several embodiments where one frame is driven in four cycles and mura phenomenon occurs between cycles, even if mura phenomenon occurs in any one area, mura phenomenon may not be transmitted to other areas.

The second wiring ADL2 may include a second-first wiring ADL2-1, a second-second wiring ADL2-2, and a second-third wiring ADL2-3. The second-first wiring ADL2-1 may be disposed at a position where the second-first power voltage line VL2-1 extends and may be separated from the second-first power voltage line VL2-1. The second-second wiring ADL2-2 may be disposed at a position where the second-second power voltage line VL2-2 extends and may be separated from the second-second power voltage line VL2-2. The second-third wiring ADL2-3 may be disposed at a position where the second-third power voltage line VL2-3 extends and may be separated from the second-third power voltage line VL2-3. The second-first wiring ADL2-1 disposed in the second area M2 may be separated from the second-first wiring ADL2-1 disposed in the third area M3, and the second-first wiring ADL2-1 disposed in the third area M3 may be separated from the second-first wiring ADL2-1 disposed in the fourth area M4. The second-second wiring ADL2-2 disposed in the third area M3 may be separated from the second-second wiring ADL2-2 disposed in the fourth area M4.

The pixels PX not connected to the second-first power voltage line VL2-1 in the first area M1 may be connected by a second-first power auxiliary line VTL2-1 extending in the second direction DR2 to apply the second power voltage. The pixels PX not connected to the second-second power voltage line VL2-2 in the second area M2 may be connected by a second-first wiring ADL2-1 extending in the first direction DR1 and a second-second power auxiliary line VTL2-2 extending in the second direction DR2 to apply the second power voltage. The pixels PX not connected to the second-third power voltage line VL2-3 in the third area M3 may be connected by a second-first wiring ADL2-1 and a second-second wiring ADL2-2 extending in the first direction DR1, and a second-third power auxiliary line VTL2-3 extending in the second direction DR2 to apply the second power voltage. The pixels PX not connected to the second-fourth power voltage line VL2-4 in the fourth area M4 may be connected by the second-first wiring ADL2-1, the second-second wiring ADL2-2, and the second-third wiring ADL2-3 extending in the first direction DR1, and the second-fourth power auxiliary line VTL2-4 extending in the second direction DR2 to apply the second power voltage. Accordingly, even if the second power voltage line VL2 is not independently connected to each of the pixels PX in the areas M1, M2, M3, M4 partitioned in the display area DA, the second power voltage may be applied to all the pixels PX.

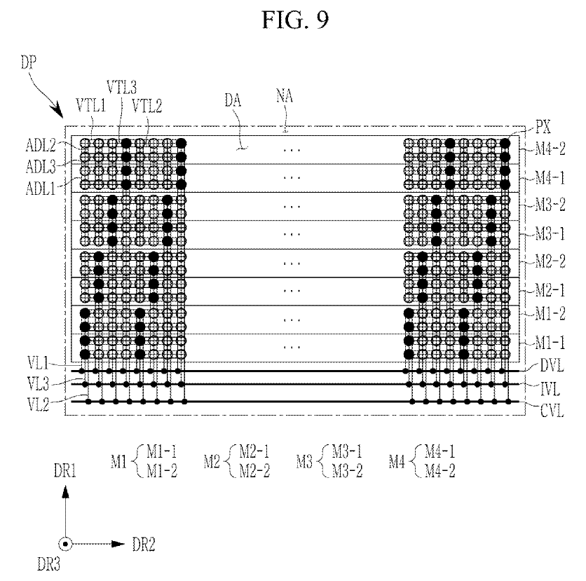

FIG. 9 is a schematic plan view of a display panel included in a display device according to an embodiment. In FIG. 9, each circle may represent a pixel PX. A filled circle represents a pixel PX among the pixels PX to which the first power voltage line VL1, the second power voltage line VL2, and the first initialization voltage line VL3 are directly connected. An empty circle represents a pixel PX among the pixels PX to which the first power voltage line VL1, the second power voltage line VL2, and the first initialization voltage line VL3 are not directly connected.

Referring to FIG. 9, the first area M1 may include a first-first area M1-1 and a first-second area M1-2. The second area M2 may include a second-first area M2-1 and a second-second area M2-2. The third area M3 may include a third-first area M3-1 and a third-second area M3-2. The fourth area M4 may include a fourth-first area M4-1 and a fourth-second area M4-2. In FIG. 9, except that the display area DA is partitioned into eight areas M1-1, M1-2, M2-1, M2-2, M3-1, M3-2, M4-1, M4-2, it may be substantially the same as the content described with reference to FIGS. 5-8. To the extent that an element is not described in detail with respect to a figure, it may be understood that the element is at least similar to a corresponding element that has been described elsewhere within the present disclosure.

The first power voltage line VL1 may include a first-first power voltage line, a first-second power voltage line, a first-third power voltage line, and a first-fourth power voltage line. The second power voltage line VL2 may include a second-first power voltage line, a second-second power voltage line, a second-third power voltage line, and a second-fourth power voltage line. The first initialization voltage line VL3 may include a first-first initialization voltage line, a first-second initialization voltage line, a first-third initialization voltage line, and a first-fourth initialization voltage line.

The first-first power voltage line, the second-first power voltage line, and the first-first initialization voltage line may be connected to pixels in the first-first area M1-1 and the first-second area M1-2. The first-second power voltage line, the second-second power voltage line, and the first-second initialization voltage line may be connected to pixels in the second-first area M2-1 and the second-second area M2-2. The first-third power voltage line, the second-third power voltage line, and the first-third initialization voltage line may be connected to pixels in the third-first area M3-1 and the third-second area M3-2. The first-fourth power voltage line, the second-fourth power voltage line, and the first-fourth initialization voltage line may be connected to pixels in the fourth-first area M4-1 and the fourth-second area M4-2.

Although FIG. 9 shows that the display area DA is partitioned into eight areas among the plurality of areas, in case that light emitting elements are driven in a plurality of cycles in one frame period, the number of the plurality of areas is not necessarily limited as long as the number of the plurality of areas is equal to or greater than the number of the plurality of cycles. For example, the plurality of areas may be partitioned into 12 areas, 16 areas, and the like.

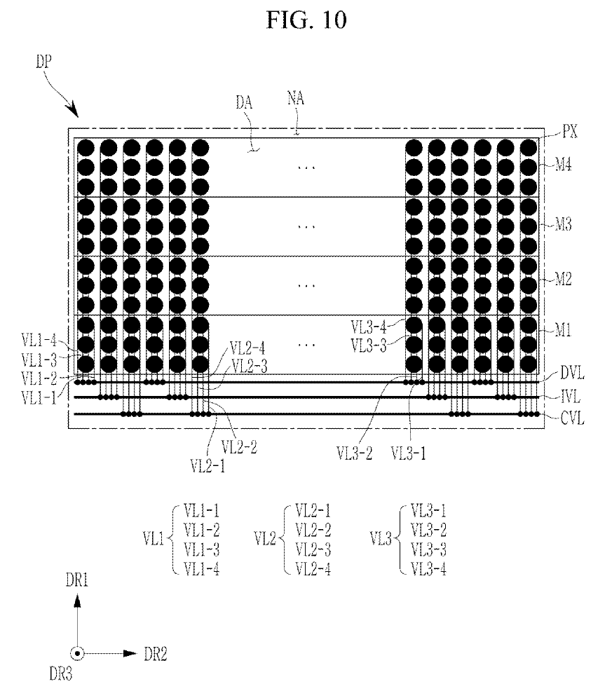

FIG. 10 is a schematic plan view of a display panel included in a display device according to an embodiment. In describing FIG. 10, descriptions of contents substantially the same as those described with reference to FIGS. 5-9 will be omitted.

Referring to FIG. 10, the first-first power voltage line VL1-1 may overlap with the first-second power voltage line VL1-2, the first-third power voltage line VL1-3, and the first-fourth power voltage line VL1-4, and may be connected to pixels PX disposed in the first area M1 not connected to the first-second power voltage line VL1-2, the first-third power voltage line VL1-3, and the first-fourth power voltage line VL1-4. The first-second power voltage line VL1-2 may overlap with the first-third power voltage line VL1-3 and the first-fourth power voltage line VL1-4, and may be connected to pixels PX disposed in the second area M2 not connected to the first-third power voltage line VL1-3 and the first-fourth power voltage line VL1-4. The first-third power voltage line VL1-3 may overlap with the first-fourth power voltage line VL1-4 and may be connected to pixels PX disposed in the third area M3 not connected to the first-fourth power voltage line VL1-4. The first-fourth power voltage line VL1-4 may be connected to pixels PX disposed in the fourth area M4.

The second-first power voltage line VL2-1 may overlap with the second-second power voltage line VL2-2, the second-third power voltage line VL2-3, and the second-fourth power voltage line VL2-4, and may be connected to pixels PX disposed in the first area M1 not connected to the second-second power voltage line VL2-2, the second-third power voltage line VL2-3, and the second-fourth power voltage line VL2-4. The second-second power voltage line VL2-2 may overlap with the second-third power voltage line VL2-3 and the second-fourth power voltage line VL2-4, and may be connected to pixels PX disposed in the second area M2 not connected to the second-third power voltage line VL2-3 and the second-fourth power voltage line VL2-4. The second-third power voltage line VL2-3 may overlap with the second-fourth power voltage line VL2-4 and may be connected to pixels PX disposed in the third area M3 not connected to the second-fourth power voltage line VL2-4. The second-fourth power voltage line VL2-4 may be connected to pixels PX disposed in the fourth area M4.

The first-first initialization voltage line VL3-1 may overlap with the first-second initialization voltage line VL3-2, the first-third initialization voltage line VL3-3, and the first-fourth initialization voltage line VL3-4, and may be connected to pixels PX disposed in the first area M1 not connected to the first-second initialization voltage line VL3-2, the first-third initialization voltage line VL3-3, and the first-fourth initialization voltage line VL3-4. The first-second initialization voltage line VL3-2 may overlap with the first-third initialization voltage line VL3-3 and the first-fourth initialization voltage line VL3-4, and may be connected to pixels PX disposed in the second area M2 not connected to the first-third initialization voltage line VL3-3 and the first-fourth initialization voltage line VL3-4. The first-third initialization voltage line VL3-3 may overlap with the first-fourth initialization voltage line VL3-4 and may be connected to pixels PX disposed in the third area M3 not connected to the first-fourth initialization voltage line VL3-4. The first-fourth initialization voltage line VL3-4 may be connected to pixels PX disposed in the fourth area M4.

Accordingly, all pixels in the display area DA may be connected to the first power voltage line VL1, the second power voltage line VL2, and the first initialization voltage line VL3. The first power voltage, the second power voltage, and the first initialization voltage may be applied to all pixels without the first wiring, the second wiring, the third wiring, the first power auxiliary line, the second power auxiliary line, and the first voltage auxiliary line. Therefore, mura phenomenon according to cycles may be suppressed while reducing the number of wirings.

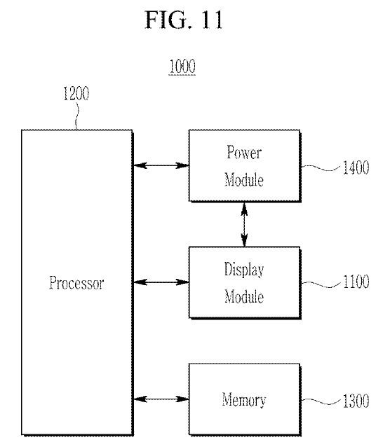

FIG. 11 is a block diagram of an electronic device according to an embodiment.

The electronic device 1000 may include electronic components and a display device. The display device may include the display device described with reference to FIGS. 1-10. The display device may include a display area and a plurality of first power voltage lines. The plurality of first power voltage lines may extend in a first direction in the display area and may apply a first power voltage to pixels disposed in the display area. The display area may include a first area, a second area, a third area, and a fourth area partitioned in the first direction. The plurality of first power voltage lines may include a first-first power voltage line connected only to pixels disposed in the first area, a first-second power voltage line connected only to pixels disposed in the second area, a first-third power voltage line connected only to pixels disposed in the third area, and a first-fourth power voltage line connected only to pixels disposed in the fourth area.

Referring to FIG. 11, the electronic device 1000 may include a display module 1100, a processor 1200, a memory 1300, a power module 1400, and the like as electronic components.

The display module 1100 may include a display panel, a driver, and the like. The display panel may include pixels displaying images and may provide a display screen. The driver may process signals to display images on the display screen of the display panel and supply them to the display panel. The driver may be provided in the form of an integrated circuit chip.

The processor 1200 may include at least one of a central processing unit (CPU), an application processor (AP), a graphic processing unit (GPU), a communication processor (CP), an image signal processor (ISP), and a controller.

Data information desirable for the operation of the processor 1200 or the display module 1100 may be stored in the memory 1300. In several embodiments where the processor 1200 executes an application stored in the memory 1300, image data signals and/or input control signals are transmitted to the display module 1100, and the display module 1100 may process the provided signals to display images through the display screen.

The power module 1400 may include a power supply module such as a power adapter or a battery device and a power conversion module that converts power supplied by the power supply module to generate power desirable for the operation of the electronic device 1000.

At least one of the respective components of the electronic device 1000 described above may be included in the display device according to the embodiments. In addition, some of the individual modules functionally included in one module may be included in the display device and others may be provided separately from the display device. For example, the display device may include the display module 1100, and the processor 1200, the memory 1300, and the power module 1400 may be provided in the form of other devices in the electronic device 1000 other than the display device.

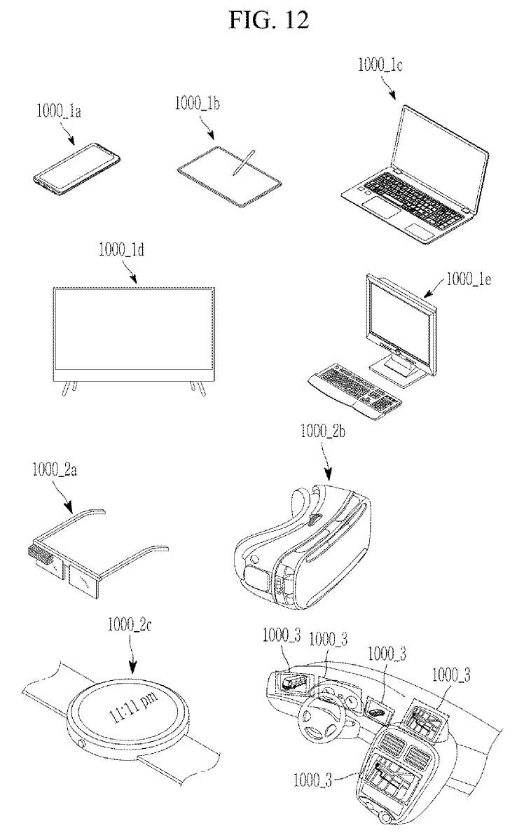

FIG. 12 shows examples of electronic devices according to various embodiments.

Referring to FIG. 12, various electronic devices to which the display device of the present disclosure may be applied include electronic devices for image display such as a smartphone 1000_1a, a tablet computer 1000_1b, a laptop computer 1000_1c, a TV 1000_1d, a desktop monitor 1000_1e, and the like. In addition, the electronic device may include wearable electronic devices including a display module such as smart glasses 1000_2a, a head mounted display 1000_2b, a smart watch 1000_2c, and the like, vehicular electronic devices 1000_3 including a display module or display device such as an instrument panel of an automobile, a center fascia, a Center Information Display (CID) disposed on a dashboard, a room mirror display, and the like.

Those skilled in the art will recognize that the present disclosure can be practiced in other specific ways without departing from its technical spirit or essential characteristics. The described embodiments should be regarded as illustrative rather than being restrictive in all aspects. Although embodiments of the present disclosure have been described with reference to the accompanying drawings, the disclosure is not necessarily limited to these embodiments and may be implemented in various forms.

What is claimed is:

1. A display device, comprising:
a display area; and
a plurality of first power voltage lines each extending in a first direction in the display area and applying a first power voltage to pixels disposed in the display area;
wherein the display area includes a first area and a second area sequentially partitioned from each other in the first direction;
wherein the plurality of first power voltage lines includes a first-first power voltage line connected only to those pixels disposed in the display area that are disposed in the first area and a first-second power voltage line connected only to those pixels disposed in the display area that are disposed in the second area.

2. The display device of claim 1, further comprising:
a first wiring disposed in the second area, wherein the first wiring is aligned with at least one of the plurality of first power voltage lines in the first direction, and wherein the first wiring is spaced apart from each of the plurality of first power voltage lines, and
wherein the pixels disposed in the second area that are not connected to the first-second power voltage line are each connected to the first wiring.

3. The display device of claim 1, wherein:
the display area further includes a third area and a fourth area sequentially partitioned from each other in the first direction; and
the plurality of first power voltage lines further includes a first-third power voltage line connected only to those pixels disposed in the display area that are disposed in the third area and a first-fourth power voltage line connected only to those pixels disposed in the display area that are disposed in the fourth area.

4. The display device of claim 3, wherein the first area, the second area, the third area, and the fourth area are sequentially disposed in the first direction.

5. The display device of claim 4, further comprising:
a plurality of first wirings disposed in the second area, the third area, and the fourth area, wherein each of the plurality of first wirings is aligned with one of the plurality of first power voltage lines in the first direction, and wherein each of the plurality of first wirings is spaced apart from each of the plurality of first power voltage lines;
wherein the plurality of first wirings includes a first-first wiring, a first-second wiring, and a first-third wiring;
wherein the pixels disposed in the second area, the pixels disposed in the third area, and the pixels disposed in the fourth area that are not connected to the first-first power voltage line are each respectively connected to the first-first wiring;
wherein the pixels disposed in the third area and the pixels disposed in the fourth area that are not connected to the first-second power voltage line are each respectively connected to the first-second wiring; and
wherein the pixels disposed in the fourth area that are not connected to the first-third power voltage line are each respectively connected to the first-third wiring.

6. The display device of claim 1, further comprising:
a plurality of first power auxiliary lines each extending in a second direction and connecting the pixels disposed in the display area, wherein the second direction is perpendicular to the first direction;
wherein the plurality of first power auxiliary lines includes a first-first power auxiliary line connected to the pixels disposed in the first area and a first-second power auxiliary line connected to the pixels disposed in the second area.

7. The display device of claim 1, further comprising:
a non-display area; and
a first power voltage transmission line extending in a second direction in the non-display area, wherein the second direction is perpendicular to the first direction;
wherein each of the plurality of first power voltage lines is connected to the first power voltage transmission line in the non-display area.

8. The display device of claim 1, further comprising:
a plurality of second power voltage lines each extending in the first direction in the display area and applying a second power voltage to the pixels disposed in the display area;
wherein the plurality of second power voltage lines includes a second-first power voltage line connected only to the pixels disposed in the first area and a second-second power voltage line connected only to the pixels disposed in the second area.

9. The display device of claim 1, further comprising:
a plurality of first initialization voltage lines each extending in the first direction in the display area and applying a first initialization voltage to the pixels disposed in the display area;
wherein the plurality of first initialization voltage lines includes a first-first initialization voltage line connected only to the pixels disposed in the first area and a first-second initialization voltage line connected only to the pixels disposed in the second area.

10. The display device of claim 1, wherein:
the first area includes a first-first area and a first-second area; and
the second area includes a second-first area and a second-second area.

11. The display device of claim 10, wherein:
the first-first power voltage line is connected only to those pixels disposed in the display area that are disposed in the first-first area and the first-second area; and
the first-second power voltage line is connected only to those pixels disposed in the display area that are disposed in the second-first area and the second-second area.

12. The display device of claim 1, wherein the first-first power voltage line overlaps with the first-second power voltage line and is connected to the pixels disposed in the first area that are not connected to the first-second power voltage line.

13. The display device of claim 1, wherein each of the pixels disposed in the display area is driven in a plurality of cycles in one frame period.

14. A display device, comprising:
a display panel comprising a display area and a non-display area surrounding the display area;
wherein the display panel includes a plurality of first power voltage lines each extending in a first direction in the display panel and applying a first power voltage to pixels disposed in the display area;
wherein the display area includes a plurality of areas sequentially partitioned from each other in the first direction; and
wherein each of the pixels disposed in the display area is driven in a plurality of cycles in one frame period.

15. The display device of claim 14, wherein a number of the plurality of areas is equal to or greater than a number of the plurality of cycles.

16. The display device of claim 14, wherein:
any one first power voltage line among the plurality of first power voltage lines is connected only to those pixels disposed in the display area that are disposed in any one area among the plurality of areas; and
adjacent first power voltage lines among the plurality of first power voltage lines are connected only to those pixels disposed in the display area that are disposed in different areas.

17. The display device of claim 14, further comprising:
a plurality of first wirings each extending in the first direction and a plurality of first power auxiliary lines each extending in a second direction perpendicular to the first direction;
wherein each of the plurality of first wirings is connected only to those pixels disposed in the display area that are not connected to any of the plurality of first power voltage lines.

18. The display device of claim 14, wherein:
any one first power voltage line among the plurality of first power voltage lines is connected only to those pixels disposed in the display area that are disposed in any one area among the plurality of areas; and
each of the plurality of first power voltage lines connected to those pixels disposed in the display area that are disposed in different areas is connected to those pixels disposed in the display area that are disposed on a same extension line in the first direction.

19. The display device of claim 14, further comprising:
a flexible printed circuit film connected to the display panel;
a driver integrated circuit chip disposed on the flexible printed circuit film;
a printed circuit board connected to the flexible printed circuit film; and
a power module disposed on the printed circuit board.

20. An electronic device, comprising:
a display device including:
a display area; and
a plurality of first power voltage lines each extending in a first direction in the display area and applying a first power voltage to pixels disposed in the display area;
wherein the display area includes a first area and a second area sequentially partitioned from each other in the first direction; and
wherein the plurality of first power voltage lines includes a first-first power voltage line connected only to those pixels disposed in the display area that are disposed in the first area and a first-second power voltage line connected only to those pixels disposed in the display area that are disposed in the second area.
